(19) United States
(12) Patent Application Publication
(10) Pub. No.: US 2022/0088644 A1
(43) Pub. Date: Mar. 24, 2022

(54) UNIT FOR REMOVING ADHESIVE LAYER AND METHOD USING THE SAME

(71) Applicant: SEMES CO., LTD., Cheonan-si (KR)

(72) Inventors: SEUNG HOON OH, Cheonan-si (KR); JIN MO JAE, Geoje-si (KR); HWAN BIN KIM, Asan-si (KR)

(73) Assignee: SEMES CO., LTD., Cheonan-si (KR)

(21) Appl. No.: 17/483,438

(22) Filed: Sep. 23, 2021

(30) Foreign Application Priority Data
Sep. 24, 2020 (KR) 10-2020-0124242

(51) Int. Cl. B08B 1/00; B08B 3/08

(52) U.S. Cl. CPC B08B 1/006; H01L 21/67028; B08B 3/08

(57) ABSTRACT

A unit for removing an adhesive layer formed in a processing chamber includes an ultrasonic generator, and a wiper soaked in a cleaning liquid. The wiper is provided to surround the ultrasonic generator.

### CROSS-REFERENCE TO RELATED APPLICATIONS

A claim for priority under 35 U.S.C. § 119 is made to Korean Patent Application No. 10-2020-0124242 filed on Sep. 24, 2020, in the Korean Intellectual Property Office, the entire contents of which are hereby incorporated by reference.

### BACKGROUND

Embodiments of the inventive concept described herein relate to a unit for removing an adhesive layer and method using the same, more specifically, a unit for removing the adhesive layer formed in a processing chamber which provides an inner space for processing a substrate, and a method using the same.

Generally, semiconductor devices are manufactured from substrates such as wafers. Specifically, the semiconductor devices are manufactured by forming fine circuit patterns on an upper surface of a substrate by performing processes such as deposition, photolithography, cleaning, drying, and etching etc.

Generally, cleaning processes include a chemical treatment to remove foreign substances from a substrate by supplying a chemical to the substrate, rinsing to remove remaining chemicals from the substrate by supplying pure water to it, and drying to remove the remaining pure water from the substrate.

A supercritical liquid is used to dry substrates. For example, the pure water on the substrate is replaced with an organic solvent, and the supercritical liquid is supplied to the upper surface of the substrate in the chamber to dissolve and remove the organic solvent remaining on the substrate. If isopropyl alcohol (IPA) is used as the organic solvent, carbon dioxide (CO₂) is used as the supercritical liquid because it has a relatively low critical temperature and critical pressure and dissolves IPA well.

The treating of substrates using the supercritical liquid is as follows. When the substrate is brought into the chamber, the supercritical carbon dioxide is supplied into the chamber to pressurize the inside of the chamber, and then the substrate is treated with the supercritical liquid while repeatedly supplying the supercritical liquid and exhausting the chamber. After treating the substrate, the chamber is exhausted and is decompressed. After exhausting the chamber, the chamber is opened to remove the substrate and repair the chamber.

Typically, chambers are provided in two independent bodies that combine and provide an internal treatment space for substrate processing. Each body is made of metal. However, when the body is driven, collisions and friction between the bodies occur. Thus, the contact surface of each body is provided with an anti-friction layer to reduce the occurrence of collisions and friction. An adhesive is used to secure the anti-friction layer to the contact surface. In the process of repairing the chamber, there is a problem that the adhesive layer may not be easily removed once it is worn away.

### SUMMARY

The purpose of the inventive concept is to easily remove an adhesive layer attached to a processing chamber.

In addition, the purpose of the inventive concept is to prevent dispersion of waste generated when removing the adhesive layer attached to the processing chamber.

The purpose of the inventive concept is not limited thereto, and other objectives not mentioned will be clearly understood by those skilled in the art from the following statements.

Embodiments of the inventive concept provide a unit for removing an adhesive layer formed in a processing chamber. In an embodiment, the unit comprises an ultrasonic generator and a wiper soaked in a cleaning liquid, wherein the wiper is provided to surround the ultrasonic generator.

In an embodiment, the ultrasonic generator further comprises a handle and a vibration generator extending from the handle and generating ultrasonic waves, the vibration generator comprising a vibrator therein, and wherein the wiper surrounds the vibration generator.

In an embodiment, the adhesive layer may be provided as an acrylic material.

In an embodiment, the cleaning liquid may be provided as an organic solvent.

In an embodiment, the cleaning liquid may be provided as a material that dissolves the adhesive layer.

In an embodiment, the cleaning liquid may be provided as an ethanol.

In an embodiment, the processing chamber may be provided as a metallic material.

In an embodiment, the processing chamber comprises a first and second body combined with an inner space for processing a substrate, an anti-friction layer formed at an interface between the first and second body, and the adhesive layer for adhering the anti-friction layer and the first or second body, wherein the anti-friction layer is provided as a polyimide (PI).

In an embodiment, the processing of substrates can be the treatment of drying substrates using the supercritical liquids inside the processing space.

Embodiments of the inventive concept provide a method for removing the adhesive layer using the adhesive layer removal unit previously mentioned, the method comprising wrapping the ultrasonic generator with the wiper soaked with the cleaning liquid, and contacting the wiper to the adhesive layer while providing the ultrasonic waves to the wiper to push the wiper in a direction.

In an embodiment, the ultrasonic generator further comprises a handle and the vibration generator extending from the handle and generating the ultrasonic waves, the vibration generator comprising the vibrator therein, and wherein the wiper surrounds the vibration generator.

In an embodiment, the adhesive layer may be provided as an acrylic material.

In an embodiment, the cleaning liquid can be provided as a material that dissolves the adhesive layer.

In an embodiment, the cleaning liquid may be provided as an organic solvent.

In an embodiment, the cleaning liquid may be provided as an ethanol.

In an embodiment, a processing chamber may be provided as a metallic material.

In an embodiment, the anti-friction layer may be provided as a polyimide (PI).

In an embodiment, the processing of substrates can be a treatment of drying the substrates using the supercritical liquids inside the processing space.

Embodiments of the inventive concept provide a method for removing an adhesive layer formed in a processing chamber, the processing chamber comprising: a first and second body combined with an inner space for processing a substrate; an anti-friction layer formed at an interface between the first and second body; and an adhesive layer for adhering the anti-friction layer and the first or second body, wherein the first and second bodies are provided as a metallic material, the anti-friction layer is provided as a polyimide (PI), and the adhesive layer is provided as an acrylic material, the method comprising wrapping the ultrasonic generator with the wiper soaked with the cleaning liquid; and contacting the wiper to the adhesive layer while providing ultrasonic wave to the wiper to push the wiper in a direction.

In an embodiment, the cleaning liquid may be provided in a material that dissolves the adhesive layer.

According to an embodiment of the inventive concept, the adhesive layer attached to the processing chamber can be easily removed.

In addition, according to an embodiment of the inventive concept, it is possible to prevent waste from being dispersed when removing the adhesive layer attached to the processing chamber.

The effects of the present invention are not limited to the above-described effects, and the effects not mentioned may be clearly understood by those of ordinary skill in the technical field to which the present invention belongs from this specification and the accompanying drawings.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a top-plan view schematically illustrating a substrate treatment apparatus according to an embodiment of the inventive concept;

FIG. 2 is a view schematically illustrating a liquid treatment device of FIG. 1.

FIG. 3 to FIG. 4 are each views schematically illustrating an embodiment of a supercritical device of FIG. 1.

FIG. 5 is a view schematically illustrating an adhesive layer formed in a processing chamber according to an embodiment.

FIG. 6 is a view schematically illustrating the appearance of an ultrasonic generator according to an embodiment.

FIG. 7 to FIG. 9 are each views schematically illustrating a removal of an adhesive layer according to an embodiment of the inventive concept.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

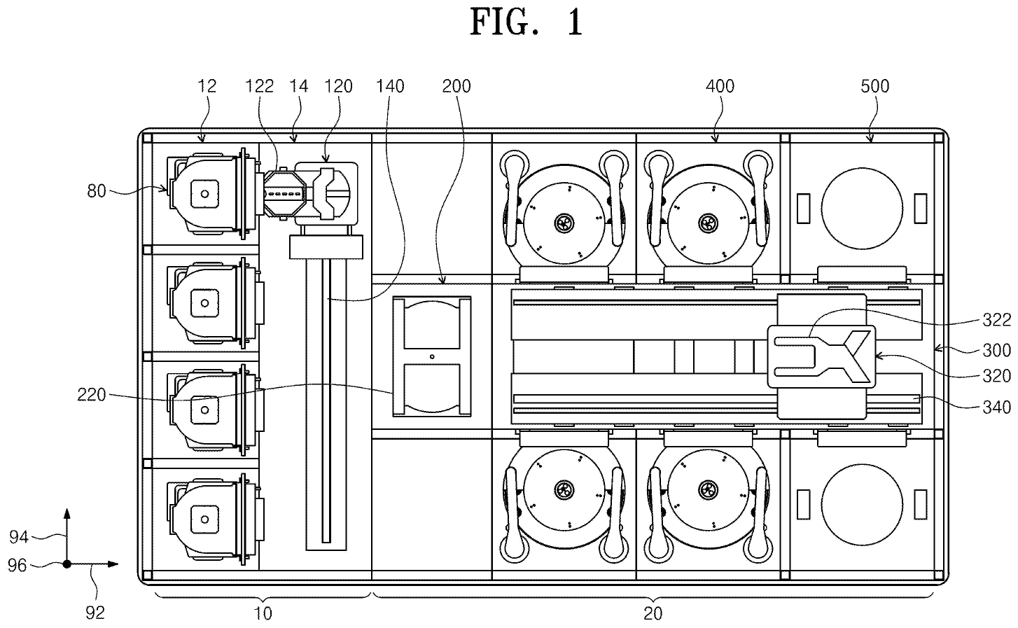

FIG. 1 illustrates a substrate treatment apparatus according to an embodiment of the inventive concept. Referring to FIG. 1, the substrate treatment apparatus comprises an index module 10, a processing module 20, and a controller (not shown). According to an embodiment, the index module 10 and the processing module 20 are arranged in a direction. Hereinafter, a direction in which the index module 10 and the processing module 20 are arranged will be referred to as a first direction 92. A direction that is perpendicular to the first direction 92 when viewed from above will be referred to as a second direction, and a direction that is perpendicular to both the first direction 92 and the second direction 94 will be referred to as a third direction 96.

The index module 10 returns the substrate W from the container 80 where the substrate W is stored to the processing module 20, and gets the processed substrate W from the processing module 20 to be stored in the container 80. The index module 10 is provided with its length extending along the second direction 94. The index module 10 has a load port 12 and an index frame 14. The index frame 14 is placed between the load port 12 and the processing module 20. The container 80 in which the substrates W are stored is placed on the load port 12. A plurality of load ports 12 may be provided, and the plurality of load ports 12 may be placed along the second direction 94.

For the container 80, a closing-type container such as the Front Open Unified Pod (FOUP) can be used. The container 80 can be placed on the load port 12 by an overhead transfer, an overhead conveyor, an automatic guided vehicle, or by an operator.

The index frame 14 is provided with an index robot 120. In the index frame 14, a guide rail 140 provided with its length extending along the second direction 94, and the index robot 120 may be provided movable on the guide rail 140. The index robot 120 includes a hand 122 on which the substrate W is placed, and the hand 122 can be provided forwardly and backwardly movable, rotatable with the third direction 96 as an axis, and movable along the third direction 96. A plurality of hands 122 are provided vertically placed apart, and the hands 122 can be forwardly and backwardly movable independent of each other.

The processing module 20 includes a buffer unit 200, a transfer device 300, a liquid treatment device 400, and a supercritical device 500. The buffer unit 200 provides a temporary space for the substrate W being brought into the processing module 20 and the substrate W being taken from the processing module 20. The liquid treatment device 400 supplies liquid to the substrate W to perform a liquid treatment process on the substrate W. The supercritical device 500 performs a drying process to remove the liquid remaining on the substrate W. The transfer device 300 transfers the substrate W between the buffer unit 200, the liquid treatment device 400, and the supercritical device 500.

The transfer device 300 may be provided with its length extending along the first direction 92. The buffer unit 200 can be placed between the index module 10 and the transfer device 300. The liquid treatment device 400 and supercritical device 500 may be placed on the side of the transfer unit 300. The liquid treatment device 400 and the transfer device 300 may be arranged in the second direction 94. The supercritical device 500 and the transfer device 300 may be arranged in the second direction 94. The buffer unit 200 may be provided at an end of the transfer device 300.

In an embodiment, the liquid treatment devices 400 may be placed on both sides of the transfer device 300, the supercritical devices 500 may be placed on both sides of the transfer device 300, and the liquid treatment devices 400 may be placed closer to the buffer unit 200 than the supercritical devices 500. On one side of the transfer device 300, liquid treatment devices 400 may be provided in an array of A×B (A, B are natural numbers greater than 1 or 1 respectively) along the first direction 92 and third direction 96 respectively. In addition, on one side of the transfer device 300, supercritical devices 500 may be provided in an array of C×D (C, D are natural numbers greater than 1 or 1 respectively) along the first direction 92 and the third direction 96 respectively. Unlike the aforementioned, only liquid treatment devices 400 may be provided on one side of the transfer device 300 and only supercritical devices 500 may be provided on the other side.

The transfer device 300 has a transfer robot 320. Within the transfer device 300, a guide rail 340 is provided with its length extending along the first direction 92 and the transfer robot 320 may be provided movable on the guide rail 340. The transfer robot 320 includes a hand 322 on which the substrate W is placed, and the hand 322 may be provided forwardly and backwardly movable, rotatable with the third direction 96 as an axis, and movable along the third direction 96. A plurality of hands 122 are provided vertically placed apart, and the hands 122 can be forwardly and backwardly movable independent of each other.

The buffer unit 200 has a plurality of buffers 220 on which the substrates W are placed. The buffers 220 may be provided placed apart from each other along the third direction 96. The buffer unit 200 has an open front side and an open rear side. The front side faces the index module 10, and the rear side faces the transfer device 300. The index robot 120 can access the buffer unit 200 through the front side and the transfer robot 320 can access the buffer unit 200 through the rear side.

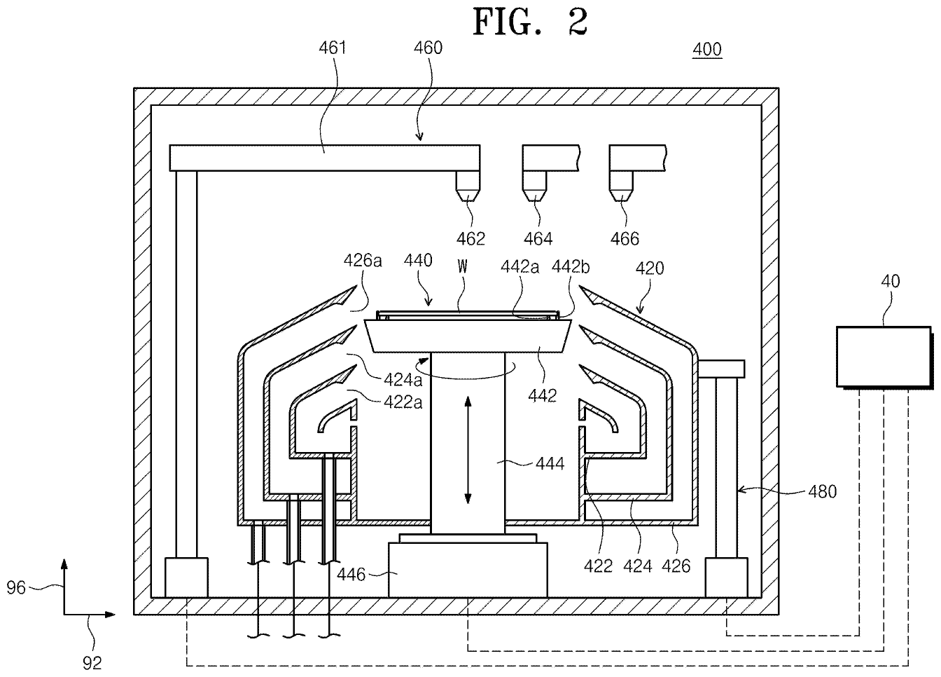

FIG. 2 illustrates an embodiment of the liquid treatment device 400 in FIG. 1. Referring to FIG. 2, the liquid treatment device 400 has a housing 410, a cup 420, a support unit 440, a liquid supply unit 460, a lift unit 480, and a controller 40. The controller 40 controls the operation of the liquid supply unit 460, the support unit 440, and the lift unit 480. The housing 410 is generally provided in a rectangular parallelepiped shape. The cup 420, the support unit 440, and the liquid supply unit 460 are located in the housing 410.

The cup 420 has a processing space with an open upper portion, and the substrate W is liquid processed within the processing space. The support unit 440 supports the substrate W within the processing space. The liquid supply unit 460 supplies the liquid onto the substrate W supported by the support unit 440. Liquid can be provided in multiple types. and supplied sequentially onto the substrate W. The lifting unit 480 adjusts the relative height between the cup 420 and the support unit 440.

In an embodiment, the cup 420 has a plurality of collecting bowls 422, 424, and 426. Each of the collecting bowls 422, 424, and 426 have a collecting space to collect the liquid used to process the substrate. Each collecting bowl 422, 424, and 426 is provided in a ring shape surrounding the support unit 440. When the liquid treatment process is carried out, the treatment liquid scattered by rotation of the substrate W flows into the collecting space through the inlets 422a, 424a, and 426a of each collecting bowl 422, 424, and 426. In an embodiment, the cup 420 has a first collecting bowl 422, a second collecting bowl 424, and a third collecting bowl 426. The first collecting bowl 422 is placed to surround the support unit 440, the second collecting bowl 424 is placed to surround the first collecting bowl 422, and the third collecting bowl 426 is placed to surround the second collecting bowl 424. The second inlet 424a that flows liquid into the second collecting bowl 424 may be located above the first inlet 422a that flows liquid into the first collecting bowl 422, and the third inlet 426a that flows liquid into the third collecting bowl 426 may be located above the second inlet 424a.

The support unit 440 has a support plate 442 and a drive shaft 444. The upper surface of the support plate 442 is generally provided in a circular shape and may have a diameter greater than the substrate W. At the center of the support plate 442, a support pin 442a is provided to support the bottom surface of the substrate W, and an upper end of the support pin 442a is provided to protrude from the support plate 442 so that the substrate W is placed apart from the support plate 442. A chuck pin 442b is provided at the edge of the support plate 442.

The chuck pin 442b is provided to protrude upwards from the support plate 442, supporting the side of the substrate W so that when the substrate W is rotated, the substrate W does not deviate from the support unit 440. The drive shaft 444 is driven by a driving member 446 and is connected to the center of the bottom surface of the substrate W and rotates the support plate 442 relative to its center axis.

In an embodiment, the liquid supply unit 460 has a first nozzle 462, a second nozzle 464, and a third nozzle 466. The first nozzle 462 supplies a first liquid onto the substrate W. The first liquid may be the liquid that removes a layer or foreign substances remaining on the substrate W. The second nozzle 464 supplies a second liquid onto the substrate W. The second liquid may dissolve well in a third liquid. For example, the second liquid may dissolve better in the third liquid than in the first liquid. The second liquid may neutralize the first liquid supplied on the substrate W. In addition, the second liquid may neutralize the first liquid and at the same time dissolve better in the third liquid compared to the first liquid.

In an embodiment, the second liquid can be water. The third nozzle 466 supplies the third liquid onto the substrate W. The third liquid may dissolve well in the supercritical liquid used in the supercritical device 500. For example, the third liquid may dissolve better in the supercritical liquid used in the supercritical device 500 compared to the second liquid. In an embodiment, the third liquid can be an organic solvent. The organic solvent may be isopropyl alcohol (IPA). In an embodiment, the supercritical liquid can be carbon dioxide.

The first nozzle 462, the second nozzle 464, and the third nozzle 466 are supported by a different arm 461 and these arms 461 can be moved independently. Optionally, the first nozzle 462, the second nozzle 464, and the third nozzle 466 may be installed on the same arm and move simultaneously.

The lifting unit 480 moves the cup 420 vertically. The relative height between the cup 420 and the substrate W is changed by the vertical movement of the cup 420. As a result, the collecting bowl 422, 424, and 426 that collects the treatment liquid changes depending on the type of liquid supplied to the substrate W, so the liquids can be separately collected. Unlike the aforementioned, the cup 420 is fixedly installed and the lift unit 480 can vertically move the support unit 440.

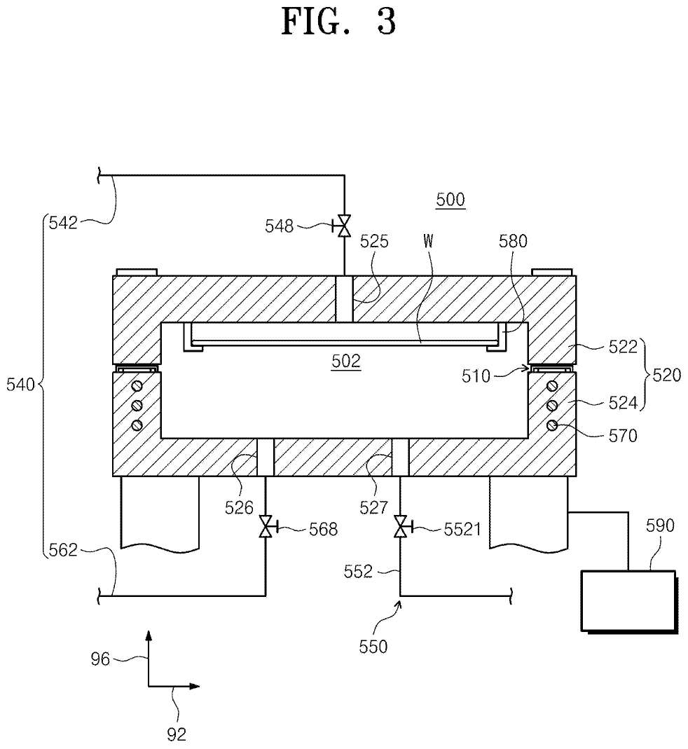

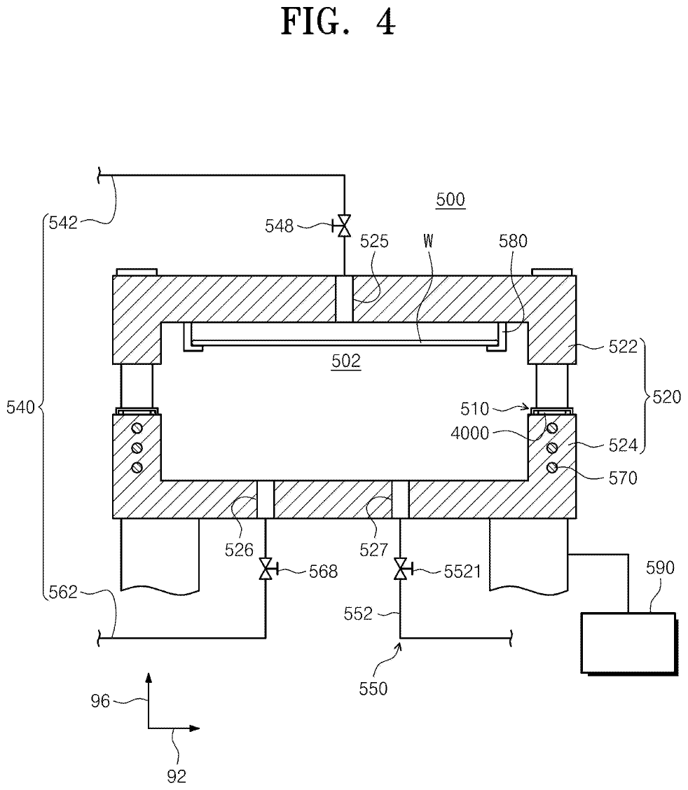

FIGS. 3 to 4 illustrate an embodiment of the supercritical device 500 in FIG. 1, respectively. According to an embodiment, the supercritical device 500 removes the liquid from the substrate W using the supercritical liquid. According to one embodiment, the liquid on the substrate W is isopropyl alcohol (IPA). The supercritical device 500 supplies supercritical liquid onto the substrate and dissolves the IPA on the substrate W in the supercritical liquid to remove the IPA from the substrate W.

The supercritical device 500 includes a processing chamber 520, a liquid supply line 540, the support unit 580, a driving member 590, and an exhaust unit 550.

The processing chamber 520 provides a processing space 502 in which the supercritical process is performed. In one example, a processing chamber 520 may be provided in a cylindrical shape. Alternatively, it may be provided in a rectangular parallelepiped shape. The processing chamber 520 has a first body 522 and a second body 524. The first body 522 and the second body 524 combine to provide the processing space 502. In one example, the first body 522 is provided in a circular shape when viewed from the top. Similarly, the second body 524 is provided in a circular shape when viewed from the top. In one example, the first body 522 is provided above the second body 524. In this case, the first body 522 and the second body 524 may open and close vertically. Optionally, the first body 522 and the second body 524 may be provided at the same height. In this case, the first body 522 and the second body 524 may open and close horizontally.

After the first body 522 and the second body 524 are decoupled to expose the processing space 502, the substrate W is brought in or out. The driving member 590 ascends or descends either the first body 522 or the second body 524 so that the processing chamber 520 is changed to the opening state or the closing state. In one example, the driving member 590 may be provided as a cylinder. The opening state is the state when the first body 522 and second body 524 are decoupled to be placed apart from each other, and the closing state is the state when the contact surfaces of the first body 522 and second body 524 contact each other to couple together. In other words, in the opening state, the processing space 502 is opened to the outside, and in the closing state, the processing space 502 is closed. In one example, the driving member 590 lifts or lowers either the first body 522 or the second body 524.

In one example, in the first body 522 a first discharge hole 525 may be formed to which a first supply line 542 is connected. Liquid can be supplied to the processing space 502 through the first discharge hole 525. In the example, in the second body 524 a second discharge hole 526 to which a second supply line 562 is connected and an exhaust hole 527 to which an exhaust line 552 is connected may be formed. Optionally, the processing chamber 520 may only be provided with either the first discharge hole 525 or the second discharge hole 526. In one example, a heater 570 is provided inside the wall of the processing chamber 520. The heater 570 heats the processing space 502 of the processing chamber 520 so that the liquid supplied into the inner space of the processing chamber 520 remains supercritical. Inside the processing space 502 an atmosphere is formed by the supercritical liquid.

The support unit 580 supports the substrate W within the processing space 502 of the processing chamber 520. The substrate W brought into the processing space 502 of the processing chamber 520 is placed on the support unit 580. For example, the substrate W is supported by the support unit 580 with the pattern surface facing upwards. In an example, the support unit 580 supports the substrate W above the second discharge hole 526. In an example, the support unit 580 may be coupled to the first body 522. Optionally, the support unit 580 may be coupled to the second body 524.

Also, the exhaust unit 550 couples to the second body 524. The supercritical liquid in the processing space 502 of the processing chamber 520 is exhausted to the outside of the processing chamber 520 through the exhaust unit 550. The exhaust unit 550 includes an exhaust line 552 and an exhaust valve 5521. The exhaust valve 5521 is installed in the exhaust line 552 to adjust the exhaust and exhaust rate of the processing space 502.

During the process, the first body 522 and the second body 524 are closely attached and the processing space 502 is sealed from the outside.

In one example, the first body 522 and the second body 524 are provided as a metallic material. For example, the first body 522 and the second body 524 may be provided as stainless steel. Shock and vibration occur on the contact surface of the first body 522 and the second body 524 during the close contact of the first body 522 and the second body 524. Thus, an anti-friction layer 510 is provided to reduce the impact and vibration on the contact surface of the first body 522 and the second body 524. In one example, the anti-friction layer 510 is provided in a ring shape on the contact surface. In one example, the anti-friction layer 510 is placed on the second body 524. In one example, the anti-friction layer 510 is provided as a polyimide (PI). The anti-friction layer 510 prevents direct contact between the first body 522 and the second body 524. In one example, the anti-friction layer 510 is 0.5 mm to 3 mm thick.

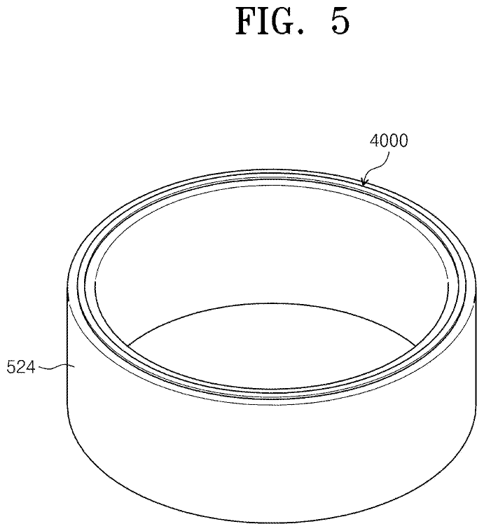

FIG. 5 illustrates the formation of an adhesive layer 4000 in the processing chamber 520 according to an embodiment of the inventive concept. Referring to FIG. 5, an adhesive layer 4000 is formed between the anti-friction layer 510 and the second body 524. The anti-friction layer 510 and the second body 524 are bonded. In one example, the adhesive layer 4000 is provided as a material that increases the adhesive strength between the processing chamber 520 provided as a metallic material and the anti-friction layer 510. In one example, the adhesive layer 4000 is provided as a material with high adhesion with metallic materials. In one example, the adhesive layer 4000 may be provided as a material with high contact with metallic materials and excellent high temperature performance. For example, the adhesive layer 4000 may be provided as an acrylic material.

In one example, the adhesive layer 4000 may be provided at a groove formed at the first body 522 or the second body 524. The groove in which the adhesive layer 4000 is provided may be formed at opposing surface(s) (i.e., contact surface(s)) of the first body 522 and the second body 524. For example, adhesive may be applied to the groove formed at the second body 524. Then, the anti-friction layer 510 with a groove is placed on top of the applied adhesive. In one example, the width of the applied adhesive may be less than the width of the groove formed at the second body 524. Optionally, the adhesive layer 4000 may be provided in the groove formed at the first body 522.

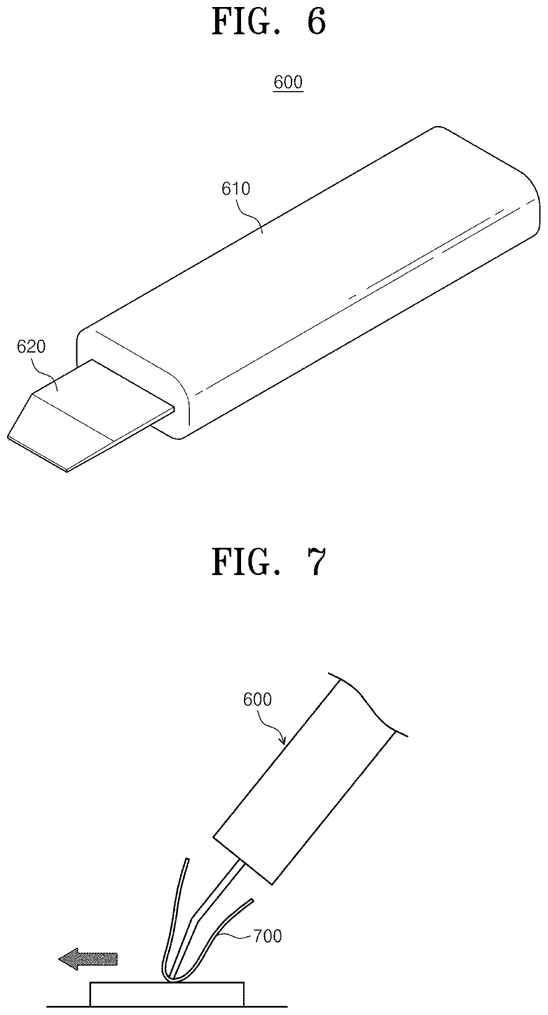

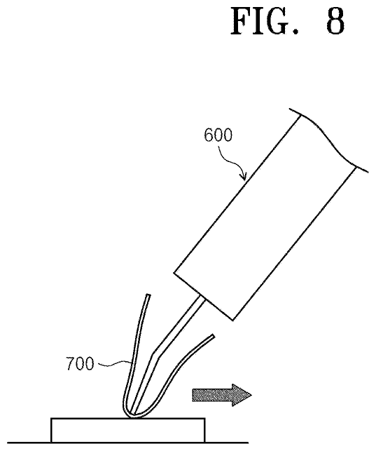

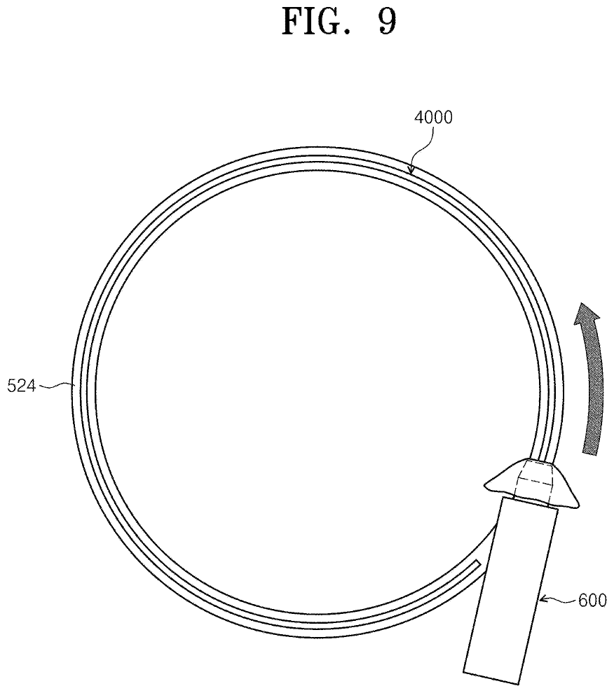

If the first body 522 and the second body 524 are repeatedly opened and closed, the adhesive will be partially lost or contaminated. Thus, the existing adhesive layer 4000 is removed and a new adhesive is applied. An embodiment of the inventive concept uses an adhesive layer removal unit to remove the existing adhesive layer 4000. FIG. 6 illustrates a shape of an ultrasonic generator 600 according to an embodiment of the inventive concept, and FIG. 7 to FIG. 9 respectively illustrate a method of removing an adhesive layer according to an embodiment of the inventive concept. Referring to FIG. 6 to FIG. 9, the adhesive layer removal unit of the inventive concept includes an ultrasonic generator 600 and a wiper 700.

In one example, the ultrasonic generator 600 has a handle 610 and a vibration generator 620. The vibration generator 620 extends from the handle 610. The operator or user can grip the handle 610 to handle the ultrasonic generator 600. The vibration generator 620 comprises a vibrator (not shown) that generates ultrasonic waves. Optionally, the vibration generator 620 can generate vibrations of frequencies other than ultrasonic waves. In one example, the vibration generator 620 may be provided in a shape in which the width becomes narrower and the thickness becomes thinner the further away from the handle 610. Optionally, the vibration generator 620 may be provided in a shape with a constant width and thickness.

Referring to FIG. 7 to FIG. 9, the adhesive layer 4000 formed in the processing chamber 520 is removed using the ultrasonic generator 600 and the wiper 700. In one example, the wiper 700 wraps around the vibration generator 620. In one example, the wiper 700 is provided soaked in a cleaning liquid. In one example, the cleaning liquid can be provided as an organic solvent. In one example, the cleaning liquid may contain an ingredient that can dissolve the adhesive. For example, the cleaning liquid may be provided as an ethanol.

The method for removing the adhesive layer 4000 is as follows. First, when after treating the substrate, the chamber is opened by placing the first body 522 and the second body 524 apart. Then the anti-friction layer 510 placed at the contact surface between the first body 522 and the second body 524 is removed. Afterwards, when the adhesive layer 4000 is exposed, the ultrasonic generator 600 is wrapped with the wiper 700 soaked in the cleaning liquid, and the operator closely contacts and pushes the wiper 700 against the adhesive. In one example, the wiper 700 wraps around the vibration generator 620. Vibration occurs at the vibration generator 620 while the operator pushes the adhesive with the wiper 700. Vibration generated by the vibration generator 620 is transmitted to the adhesive layer 4000 via the wiper 700 that serves as a medium. Thus, the adhesive can be removed more easily than when the operator removes the adhesive layer 4000 by hand. Consequently, the problem of the existing adhesive layer 4000 not being properly removed and subsequently entering into the processing space to affect processing, can be reduced. As shown in FIG. 7 to FIG. 9, the operator moves the ultrasonic generator 600 in one direction only. Therefore, the problem of adhesives clumping together in the process of removing the existing adhesive layer 4000 can be reduced.

In the aforementioned example, the adhesive layer removal unit of the inventive concept was illustrated as intending to clean the processing chamber 520 provided in the supercritical device 500. In contrast, however, the adhesive layer removal unit of the inventive concept can also be used to clean other subjects to remove substances with adhesive properties.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A unit for removing an adhesive layer formed in a processing chamber, the unit comprising:
an ultrasonic generator; and
a wiper soaked in a cleaning liquid,
wherein the wiper is provided to surround the ultrasonic generator.

2. The unit of claim 1, wherein the ultrasonic generator further comprises a handle and a vibration generator extending from the handle and generating ultrasonic waves, the vibration generator comprising a vibrator therein, and
wherein the wiper surrounds the vibration generator.

3. The unit of claim 1, wherein the adhesive layer is provided as an acrylic material.

4. The unit of claim 1, wherein the cleaning liquid is provided as an organic solvent.

5. The unit of claim 1, wherein the cleaning liquid is provided as a material that dissolves the adhesive layer.

6. The unit of claim 5, wherein the cleaning liquid is provided as an ethanol.

7. The unit of claim 1, wherein the processing chamber is provided as a metallic material.

8. The unit of claim 1, wherein the processing chamber comprises:
a first and second body combined with an inner space for processing a substrate;
an anti-friction layer formed at an interface between the first and second body; and
the adhesive layer for adhering the anti-friction layer and the first or second body,
wherein the anti-friction layer is provided as a polyimide.

9. The unit of claim 8, wherein the processing chamber uses a supercritical liquid to dry the substrate disposed therein.

10.-20. (canceled)
